(19) United States
(12) Patent Application Publication
(10) Pub. No.: US 2012/0152587 A1
(43) Pub. Date: Jun. 21, 2012

(54) Wall Plate and Method of Use Thereof

(76) Inventors: Louis Lemire, Grand-Mere (CA); Francois Drolet, Trois-Riviers (CA)

(21) Appl. No.: 13/327,926

(22) Filed: Dec. 16, 2011

Related U.S. Application Data
(60) Provisional application No. 61/424,742, filed on Dec. 20, 2010.

(51) Int. Cl. H05K 5/03; H01R 43/20

(52) U.S. Cl. 174/66; 29/876

(57) ABSTRACT

A wall plate for mounting and supporting an electrical controller (e.g. a switch), an electronic controller (e.g. an electronic thermostat), or a similar wall-mounted electrical equipment, to an electrical outlet box is disclosed. The wall plate is configured to be secured to the outlet box via fasteners. The wall plate comprises a generally central opening through the electrical wires located in the outlet box can be accessed. The wall plate also comprises at least one outwardly extending lug configured to be received in a corresponding recess in the controller, and an outwardly extending supporting base configured to support and secure the controller to the wall plate. The wall plate allows the controller to be mounted to it instead of being mounted to the outlet box, thereby easing the installation of electrical and/or electronic controller.

### CROSS-REFERENCE TO RELATED APPLICATIONS

The present patent application claims the benefits of priority of commonly assigned U.S. Provisional Patent Application No. 61/424,742, entitled “Wall Mount Plate and System” and filed at the United States Patent and Trademark Office on Dec. 20, 2010; the content of which is incorporated herein by reference.

### FIELD OF THE INVENTION

The present invention generally relates to electrical equipments and apparatuses and more particularly to accessories for use with electrical equipments and apparatuses.

### BACKGROUND OF THE INVENTION

Every day, electrical outlet boxes are installed behind walls in order to provide and house the electrical wires which are to be connected to wall mounted electrical controllers such as switches, bi-metal thermostats, etc., or electronic controllers such as electronic thermostats, air-conditioner control panels, etc.

Still, despite the constant evolution of the controllers mounted to the outlet boxes, the way in which the controllers are mounted to these outlet boxes has not really evolved at the same pace. In fact, in order to mount a controller to an outlet box, the technique still involves the direct screwing of the controller to the threaded tabs or lugs extending inside the outlet box.

The main problem with this technique is that when the controller is ready to be mounted near the wall, it is often impossible to see the threaded tabs and thus to align the screw holes of the controller with the holes in the threaded tabs. Hence, the installation typically involves several unsuccessful attempts to align the screw holes of the controller with the holes of the threaded tabs before being able to secure the screws through the screw holes and into the holes in the threaded tabs.

Hence, there is a need for a way to mitigate the difficulties in mounting electrical and electronic controllers, and possibly other electrical equipments, to electrical outlet boxes.

### SUMMARY OF THE INVENTION

In accordance with the principles of the present invention, the difficulties in mounting electrical and electronic controllers to electrical outlet boxes are mitigated by a wall plate which can be directly mounted to the outlet box and which is configured to removably receive and support the electrical or electronic controller.

Hence, a wall plate in accordance with the principles of the present invention is typically made of polymeric materials (e.g. plastic) and is generally sized and shaped to cover the generally rectangular opening of the outlet box. The plate also comprises typically two fastener holes which are configured to be aligned with the holes in the threaded tabs in the outlet box. In that sense, the configuration of outlet boxes is relatively standard. Still, the fastener holes may be made oblong to allow some room for lateral adjustment.

The wall plate also comprises a large central opening which is configured to allow access to the interior of the outlet box and to the electric wires which are located in the outlet box.

The wall plate also comprises at least one supporting lug which extends outwardly from the plate (i.e. away from the outlet box). The supporting lug is configured to be received in a corresponding supporting recess or hole in the back of the controller.

The wall plate also comprises a supporting base which extends outwardly from the lower edge of the plate. The supporting base is configured to support and secure the controller to the wall plate. In that sense, the supporting base is typically provided with at least one fastener hole or notch for receiving the fastener which will secure the controller to the supporting base.

In typical though non-limitative embodiments of a wall plate in accordance with the principles of the present invention, the top edge of the plate is provided with at least one alignment mark (e.g. a line) configured to assist in the alignment of the controller with the wall plate during installation. In such typical though non-limitative embodiments, the at least one mark is aligned with the at least one fastener hole or notch in the supporting base.

In accordance with the principles of the present invention, the wall plate is generally configured to be mounted first to the outlet box. In that sense, as the wall plate is relatively thin and light, it is generally easier to align the fastener holes of the wall plate with the holes in the threaded tabs of the outlet box. Then, when the wall plate is properly mounted to the outlet box, the controller simply needs to be connected to the electrical wires and then mounted and secure to the wall plate.

Other and further aspects and advantages of the present invention will be obvious upon an understanding of the illustrative embodiments about to be described or will be indicated in the appended claims, and various advantages not referred to herein will occur to one skilled in the art upon employment of the invention in practice. The features of the present invention which are believed to be novel are set forth with particularity in the appended claims.

### BRIEF DESCRIPTION OF THE DRAWINGS

The above and other aspects, features and advantages of the invention will become more readily apparent from the following description, reference being made to the accompanying drawings in which:

FIG. 1 is a side perspective view of an embodiment of a wall plate in accordance with the principles of the present invention shown with an electrical outlet box.

FIG. 2 is a front perspective view of the wall plate of FIG. 1.

FIG. 3 is a rear perspective view of the wall plate of FIG. 1.

FIG. 4 is a front view of the wall plate of FIG. 1.

FIG. 5 is a rear view of the wall plate of FIG. 1.

FIG. 6 is a cross-sectional side view of the wall plate of FIG. 1 along lines 6-6 in FIG. 4.

FIG. 7 is a top view of the wall plate of FIG. 1.

FIG. 8 is a bottom view of the wall plate of FIG. 1.

FIG. 9 is a side perspective view of the wall plate of FIG. 1 shown with an electronic controller.

FIG. 10A is a top view of the electronic controller and the wall plate of FIG. 1 during installation.

FIG. 10B is a side view of the electronic controller and the wall plate of FIG. 1 during installation.

FIG. 11 is a front perspective view of another embodiment of a wall plate in accordance with the principles of the present invention.

FIG. 12 is a front view of still another embodiment of a wall plate in accordance with the principles of the present invention.

### DETAILED DESCRIPTION OF THE PREFERRED EMBODIMENT

A novel wall plate and a method of use thereof will be described hereinafter. Although the invention is described in terms of specific illustrative embodiments, it is to be understood that the embodiments described herein are by way of example only and that the scope of the invention is not intended to be limited thereby.

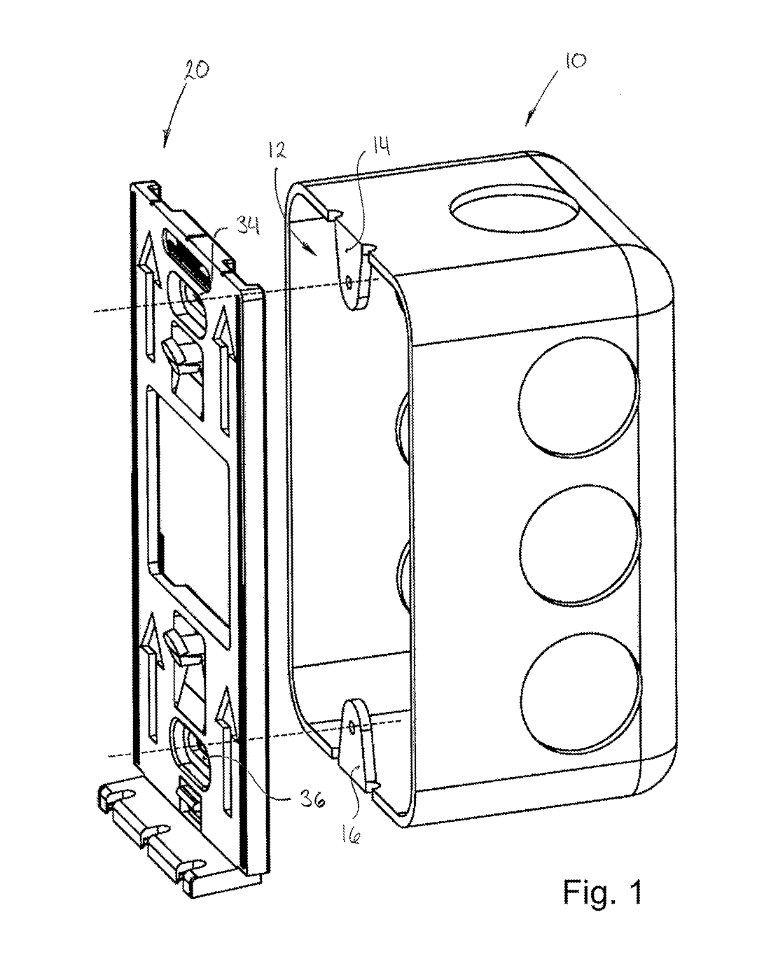

Referring first to FIG. 1, an embodiment of a wall plate 20 in accordance with the principles of the present invention is shown. As illustrated, the wall plate 20 is configured to be mounted to an outlet box 10, typically mounted to a stud behind a wall, such as to provide support for an electrical controller (e.g. a switch, a bimetal thermostat, etc.), an electronic controller (e.g. a thermostat, an air-conditioner control panel, etc.), or another similar wall-mounted electrical equipment. Without limitations, the present embodiment of the wall plate 20 will be described in conjunction with an electronic controller 80 (e.g. a thermostat).

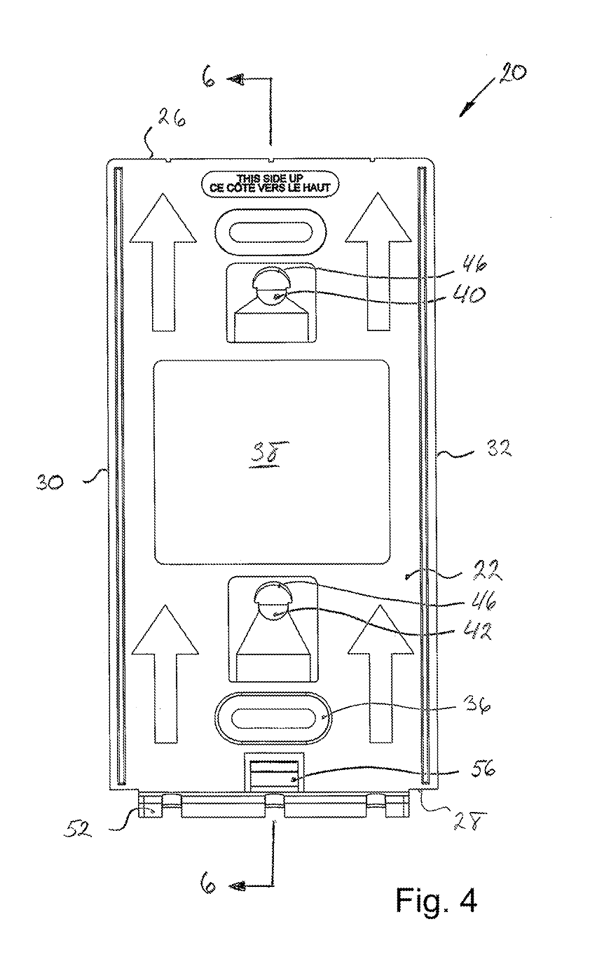

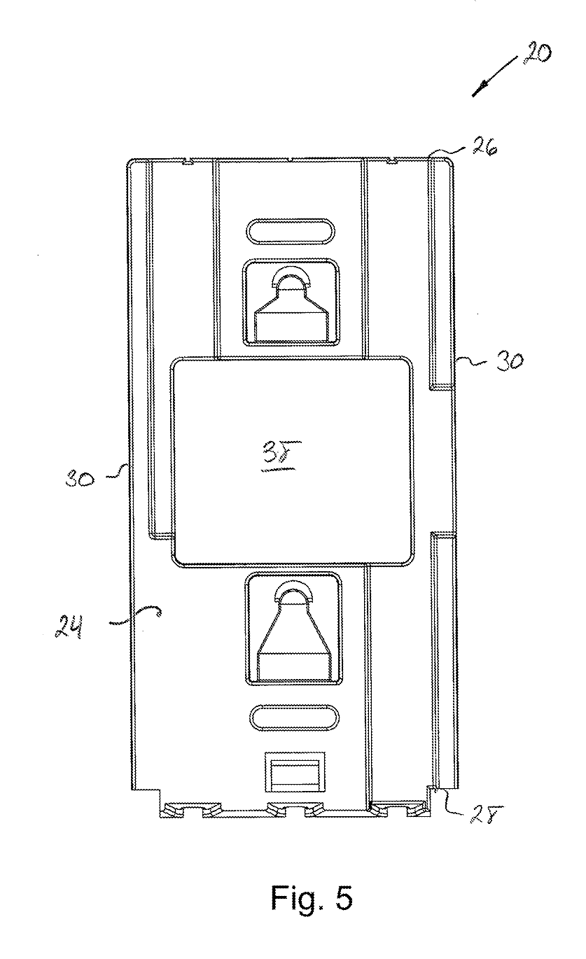

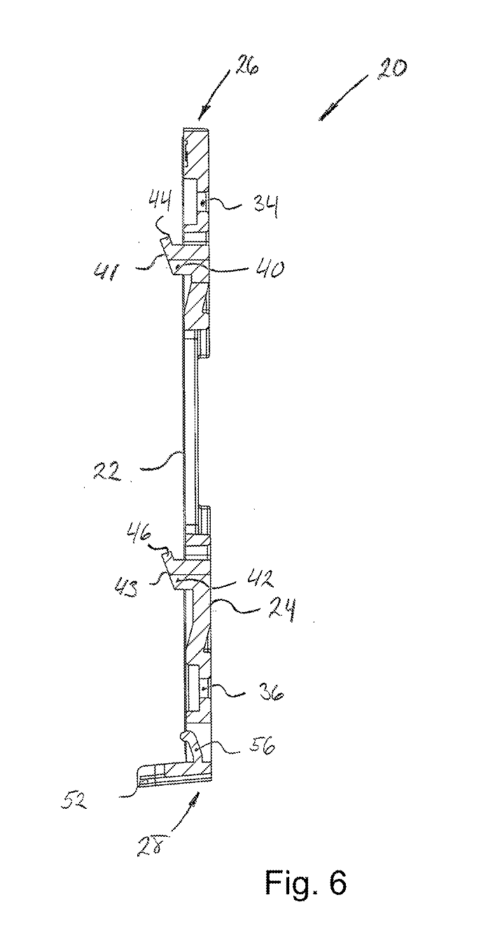

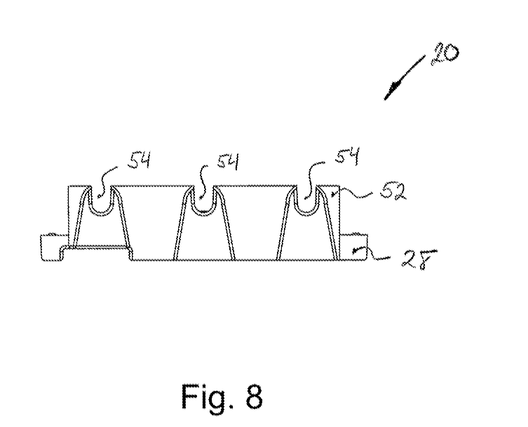

The wall plate 20 is generally substantially flat (see FIGS. 6, 7 and 8) and of rectangular shape (see FIGS. 4 and 5) and is suitably sized to generally cover the opening 12 of the outlet box 10.

In the present embodiment, the wall plate 20 is made from polymeric material, i.e. plastic, such as, but not limited to, ABS plastic. In other embodiments, the wall plate 20 could be made of other materials. Still, since the wall plate 20 is to be mounted to an electrical outlet box 10, the wall plate 20 should preferably be made of electrically insulating materials.

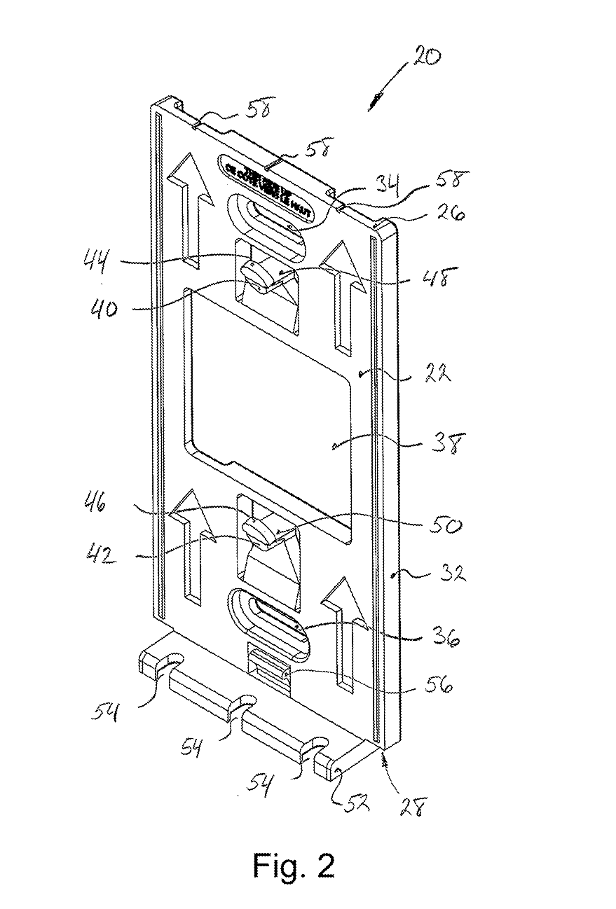

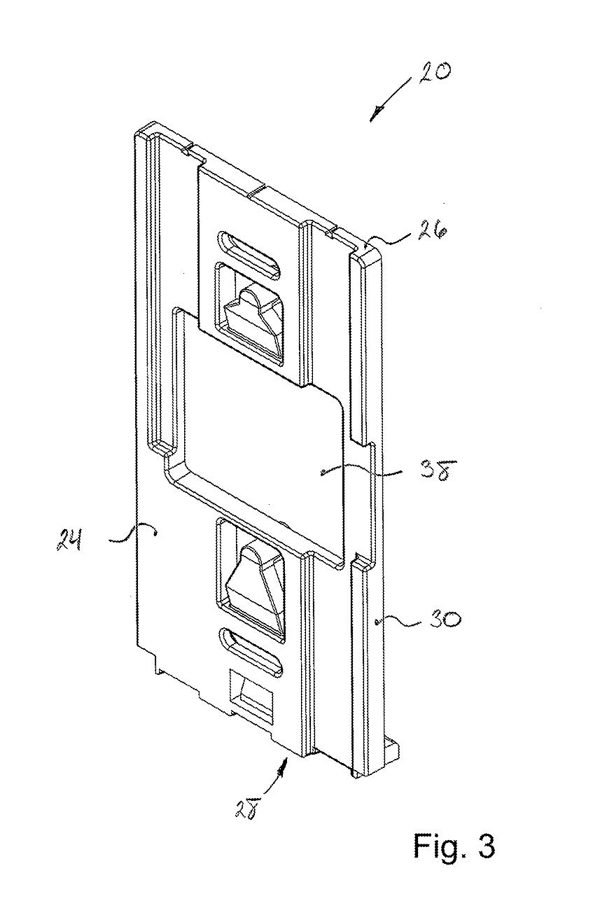

Referring now to FIG. 1 and more particularly to FIGS. 2-8, the wall plate 20 generally comprises a front (or outer) side 22 configured to face away from the outlet box 10, a rear (or inner) side 24 configured to face the outlet box 10, an upper edge 26, a lower edge 28, a left side edge 30, and a right side edge 32.

To mount the wall plate 20 to the outlet box 10, the wall plate 20 is provided with two fastener holes 34 and 36 respectively located near the upper edge 26 and lower edge 28. As best shown in FIG. 1, the fastener holes 34 and 36 are positioned such as to be aligned with the threaded tabs 14 and 16 of the outlet box 10. The fastener holes 34 and 36 are also suitably sized to receive regular mounting fasteners, typically screws.

As best shown in FIGS. 2 and 6, in the present embodiment, the fastener holes 34 and 36 are counterbored in order to prevent the heads of the fasteners (not shown) from protruding from the front side 22 of the wall plate 20. The counterbore configuration of the fastener holes 34 and 36 allows the heads of the fasteners to be located within the thickness of the wall plate 20.

In addition, in the present embodiment, the fastener holes 34 and 36 are made oblong such as to provide room for adjustment, typically lateral adjustment, of the wall plate 20 with respect to the outlet box 10.

In order to provide access to the interior of the outlet box 10, the wall plate 20 comprises an access opening 38, generally centrally located with respect to the width and height of the wall plate 20. The access opening 38 is typically made large enough to easily see inside the outlet box 10 and to easily access the electrical wires located in the outlet box 10. Though in the present embodiment, the access opening 38 is generally rectangular in shape, in other embodiments, the shape of the access opening could be different (e.g. square, circular, elliptical, etc.).

As it will be best understood below, in order to provide support to the controller 80, the wall plate 20 comprises two lugs 40 and 42 extending outwardly therefrom.

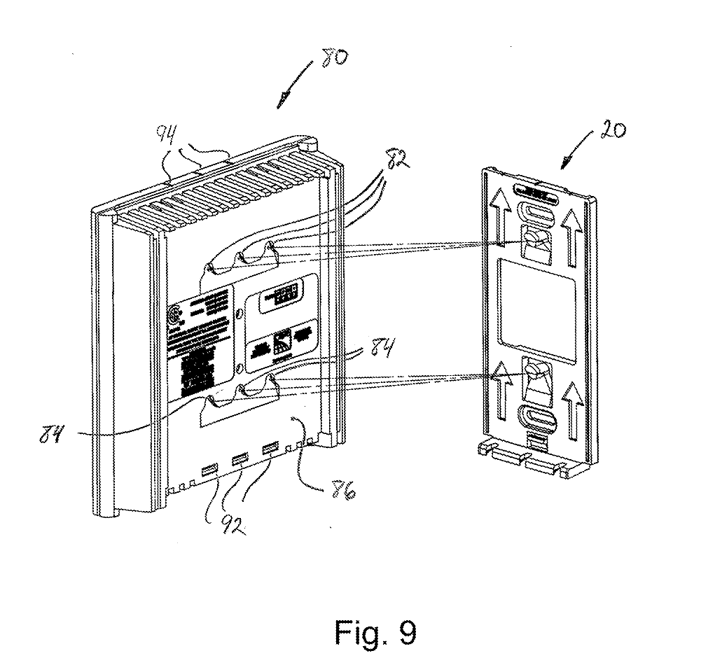

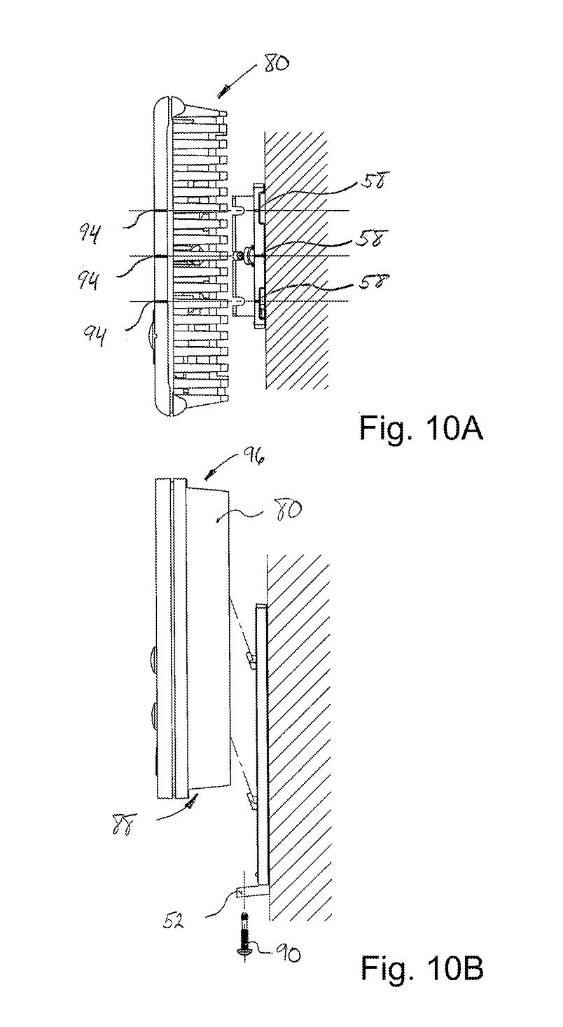

The lugs 40 and 42 are configured to receive and support the controller 80 (see FIGS. 9 and 10B). In that sense, the lugs 40 and 42 are configured to extend in mounting recesses 82 and 84 located at the back 86 of the controller 80 (see FIG. 9) when the controller 80 is mounted to the wall plate 20. To properly receive and support the controller 80, the lugs 40 and 42 are respectively provided, at their respective extremities 41 and 43, with partial flanges or lips 44 and 46. As best shown in FIGS. 2 and 6, the partial flanges 44 and 46 extend substantially upwardly such as to respectively engage mounting recesses 82 and 84. The partial flanges 44 and 46 therefore generally prevent the controller 80 to be simply pulled from the wall plate 20 during use.

Also, in order to provide stable receiving and supporting surfaces for the mounting recesses 82 and 84, the respective upper portions 48 and 50 of the lugs 40 and 42 are substantially rounded.

In the present embodiment, the lugs 40 and 42 are substantially centrally located with respect to the width of the wall plate 20. The central location of the lugs 40 and 42 allows for maximal lateral adjustment of the position of the controller 80 with respect to the wall plate 20 (see FIG. 9).

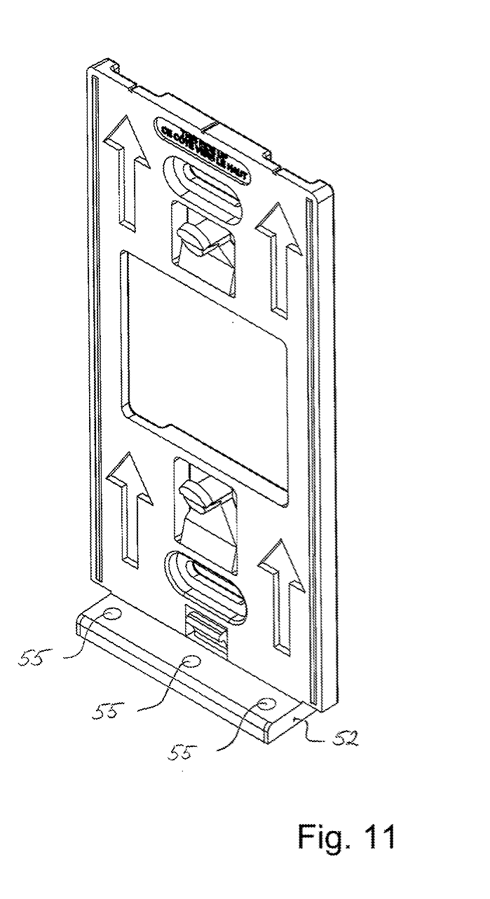

As best shown in FIGS. 2, 4 and 6, in the present embodiment, the wall plate 20 also comprises a laterally extending supporting base 52 outwardly extending from or near the lower edge 28. As it will be best understood below, the support base 52 is configured to receive the lower side 88 of the controller 80 and to be secured thereto. In that sense, as best shown in FIG. 2, in the present embodiment, the supporting base 52 comprises several laterally spaced fastener notches 54 which can receive fasteners 90 used to secure the supporting base 52 to the lower side 88 of the controller 80 (see FIG. 10B). In other embodiments (see FIG. 11), the supporting base 52 could comprise fastener holes 55 instead of fastener notches 54.

In the present embodiment, the supporting base 52 is notably not perfectly perpendicular with respect to the wall plate 20 (see FIG. 6). In fact, in the present embodiment, the supporting base 52 extends at a slightly downward angle in order to match the configuration of the lower side 88 of the controller 80.

Still referring more particularly to FIGS. 2, 4 and 6, the wall plate 20 also comprises an alignment tongue 56 which is located between the lower fastener hole 36 and the supporting base 52 and substantially centrally with respect to the width of the wall plate 20. The alignment tongue 56 generally serves to engage one of corresponding recesses 92 at the back 86 of the controller 80 during installation (see FIG. 9).

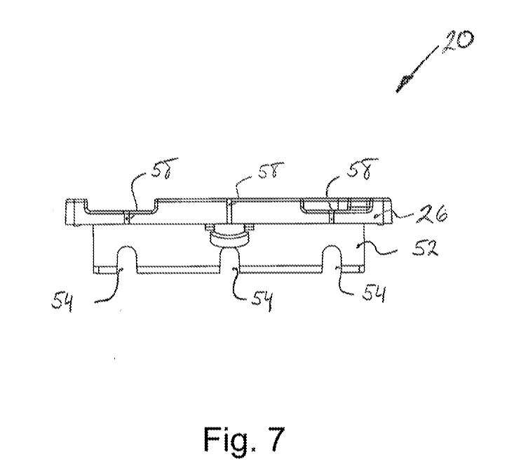

In the present embodiment, the upper edge 26 of the wall plate 20 comprises several alignment marks or lines 58. As best illustrated in FIG. 7, the alignment marks 58 are substantially aligned with the fastener notches 54 in the supporting base 52. As it will be best understood below, the alignment marks 58 are configured to assist the user in properly aligning the controller 80 with the wall plate 20 during the installation of the controller 80 (see FIG. 10A). Understandably, the controller 80 is preferably provided with corresponding alignment marks 94 on its upper side 96.

In use, the wall plate 20 is typically first installed to the outlet box 10. To do so, the fastener holes 34 and 36 are aligned with the threaded tabs 14 and 16 of the outlet box 10 and mounting fasteners, typically screws, are then mounted through the fastener holes 34 and 36 and into the threaded tabs 14 and 16. If necessary, the position of the wall plate 20 with respect to the outlet box 10 can be slightly adjusted via the oblong shape of the fastener holes 34 and 36.

Once properly mounted to the outlet box 10, the wall plate 20 allows access to the interior of the outlet box 10, via the access opening 38, in order for the electrical wires (not shown) located in the outlet box 10 to be slightly pulled out and connected to the controller 80.

Once the controller 80 is properly connected to the electrical wires, the controller 80 is ready to be mounted to the wall plate 20. To do so, as best shown in FIGS. 10A and 10B, the controller 80 is positioned slightly higher than the wall plate 20 (see FIG. 10B) and the alignment marks 94 located to the upper side 96 of the controller 80 are then aligned with the alignment marks 58 located on the upper edge 26 of the wall plate 20 (see FIG. 10A).

Once the controller 80 is properly aligned with the wall plate 20, the controller 80 is lowered onto the wall plate 20 such that the lugs 40 and 42 are respectively received into the mounting recesses 82 and 84 located at the back 86 of the controller 80. At this point, the lower side 88 of the controller 80 should rest on the supporting base 52.

Then, to finally secure the controller 80 to the wall plate 20, at least one securing fastener 90, i.e. a securing screw, is mounted through at least one of the fastener notches 54 and into at least one threaded receiving hole (not shown) in the lower side 88 of the controller 80.

To remove the controller 80 from the wall plate 20, the above steps are generally performed in reverse.

Understandably, by mounting the wall plate 20 first to the outlet box 10 and then mounting the controller 80 to the wall plate 20, the overall process of mounting a controller 80 to an outlet box 10 is faster and easier since the wall plate 20 is more easily mounted to the outlet box 10 and then the controller 80.

Understandably, though the present embodiment of the wall plate 20 is particularly configured to be mounted to a regular single gang outlet box 10, the wall plate 20 could possibly be mounted to one gang of a multiple gangs outlet box.

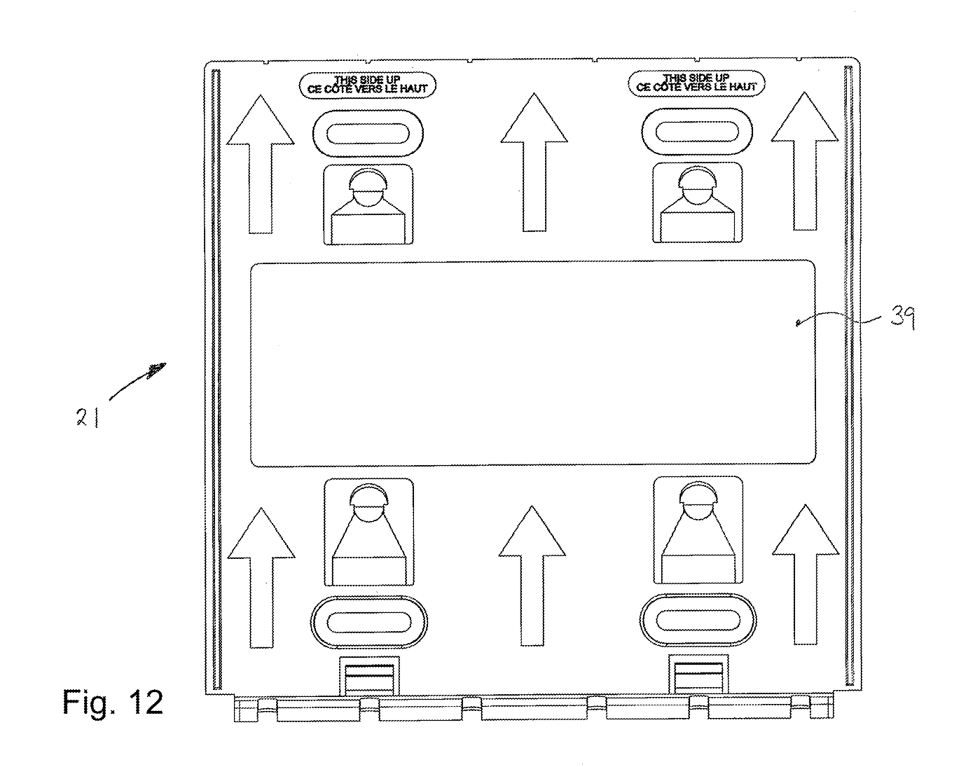

Still, in other embodiments (see FIG. 12), the wall plate 21 could be configured to be mounted to several gangs of a multiple gangs outlet box. In such embodiments, the wall plate 21 would typically more or less comprise the equivalent of several wall plates 20 located side by side and preferably unitarily. However, in such embodiments, the wall plate 21 could be adapted to take advantage of its larger size by having, for instance, a larger access opening 39.

While illustrative and presently preferred embodiments of the invention have been described in detail hereinabove, it is to be understood that the inventive concepts may be otherwise variously embodied and employed and that the appended claims are intended to be construed to include such variations except insofar as limited by the prior art.

1) A wall plate for supporting an electrical equipment to an electrical outlet box, the outlet box comprising at least two threaded tabs, the wall plate comprises a front side and a rear side, a first side edge and a second side edge, an upper edge and a lower edge, the wall plate comprises at least two fastener openings configured to be in alignment with the at least two threaded tabs, the wall plate comprises at least one access opening, the wall plate comprises at least one outwardly extending lug configured to engage and support the electrical equipment.

2) A wall plate as claimed in claim 1, wherein the wall plate comprises at least two outwardly extending lugs.

3) A wall plate as claimed in claim 1, wherein the wall plate comprises a supporting base outwardly extending from the lower edge of the wall plate.

4) A wall plate as claimed in claim 3, wherein the supporting base comprises at least one fastener notch.

5) A wall plate as claimed in claim 3, wherein the supporting base comprises several fastener notches.

6) A wall plate as claimed in claim 3, wherein the supporting base comprises at least one fastener opening.

7) A wall plate as claimed in claim 3, wherein the supporting base comprises several laterally spaced fastener openings.

8) A wall plate as claimed in claim 1, wherein the upper edge of the wall plate comprises at least one alignment mark.

9) A wall plate as claimed in claim 1, wherein the upper edge of the wall plate comprises several laterally spaced alignment marks.

10) A wall plate as claimed in claim 1, wherein the upper edge comprises at least one alignment mark, wherein the wall plate comprises a supporting base outwardly extending from the lower edge thereof, wherein the supporting base comprises at least one fastener notch, and wherein the at least one alignment mark and the at least one fastener notch are aligned.

11) A wall plate as claimed in claim 1, wherein the upper edge comprises at least one alignment mark, wherein the wall plate comprises a supporting base outwardly extending from the lower edge thereof, wherein the supporting base comprises at least one fastener opening, and wherein the at least one alignment mark and the at least one fastener opening are aligned.

12) A wall plate as claimed in claim 1, wherein the electrical equipment is an electric controller or an electronic controller.

13) A method for mounting an electrical equipment to an electrical outlet box using a wall plate, the electrical equipment comprising at least one rear mounting recess, the outlet box having electrical wires extending therein, and comprising at least two threaded tabs, the wall plate comprising at least two fastener openings configured to be in alignment with the at least two threaded tabs, at least one access opening, and at least one outwardly extending lug configured to engage and support the electrical equipment, the method comprising:
aligning the at least two fastener openings of the wall plate with the at least two threaded tabs of the outlet box;
threading a threaded fastener through each of the at least two fastener openings and into each of the at least two threaded tabs;
connecting the electrical wires to the electrical equipment;
aligning the at least one rear mounting recess of the electrical equipment with the at least one outwardly extending lug;
mounting the electrical equipment to the at least one outwardly extending lug.

14) A method as claimed in claim 13, wherein the wall plate comprises an upper edge, the upper edge comprising at least one first alignment mark, wherein the electrical equipment comprises an upper side, the upper side comprising at least one second alignment mark, and wherein the method further comprises the step of:
aligning the at least one second alignment mark with the at least one first alignment mark.

15) A method as claimed in claim 13, wherein the wall plate comprises a lower edge and wherein a supporting base outwardly extends from the lower edge, wherein the electrical equipment comprises lower side, and wherein the method further comprises the step of:
resting the lower side of the electrical equipment onto the supporting base.

16) A method as claimed in claim 13, wherein the supporting base is configured to receive at least one fastener and wherein the lower side of the electrical equipment is configured to receive the at least one fastener, and wherein the method further comprises the step of:
securing the lower side of the electrical equipment to the supporting base via the at least one fastener.
